(19) United States
(12) Patent Application Publication
(10) Pub. No.: US 2026/0248038 A1
(43) Pub. Date: Aug. 20, 2026

(54) WAFER STACKING STRUCTURE AND FABRICATING METHOD OF THE SAME

(71) Applicant: UNITED MICROELECTRONICS CORP., Hsin-Chu City (TW)

(72) Inventors: Chu-Fu Lin, Kaohsiung City (TW); Chuan-Lan Lin, Chiayi City (TW); Chun-Hung Chen, Tainan City (TW)

(73) Assignee: UNITED MICROELECTRONICS CORP., Hsin-Chu City (TW)

(21) Appl. No.: 19/075,728

(22) Filed: Mar. 10, 2025

(30) Foreign Application Priority Data
Feb. 18, 2025 (TW) 114105829

(51) Int. Cl. H01L 23/00; H01L 25/16; H10B 80/00

(52) U.S. Cl. CPC H10W 90/00; H10B 80/00; H10W 72/0198

(57) ABSTRACT

A wafer stacking structure includes device wafers. Each device wafer is designated as an Nth device wafer. N=1, 2, . . . , M, M≥3. N is a positive integer that increases sequentially in Arabic numerical order starting from 1 to define a series of Nth device wafers. The Nth device wafers are stacked from bottom to top to form a wafer stacking structure. Each of the Nth device wafers includes an Nth front surface and an Nth back surface. An Nth metal interconnection is embedded within an Nth dielectric layer. The Nth metal interconnection and the Nth dielectric layer cover and contact the Nth front surface of each Nth device wafer. Edges of all the Nth device wafers are aligned to form a plane when N=1, 2, . . . , M−1, and an edge of an Mth dielectric layer of the Mth device wafer protrudes from the plane.

### BACKGROUND OF THE INVENTION

### 1. Field of the Invention

The invention relates to a wafer stacking structure and a fabricating method of the same, particularly to a wafer stacking structure uses silicon as a carrier wafer and the fabricating method thereof.

### 2. Description of the Prior Art

Wafer stacking technology is a critical packaging technique in the semiconductor industry. By vertically stacking multiple wafers or chips, it enables high-density integration while reducing package size. As chip sizes continue to shrink, traditional planar packaging methods are increasingly inadequate to meet the growing demands for high-performance computing and high-capacity storage. As a result, wafer stacking has emerged as a vital solution to address these challenges. This technology allows the integration of chips with diverse functionalities and the use of vertical interconnection techniques, significantly enhancing processing power and storage capacity while minimizing space requirements. It is particularly beneficial for high-performance computing, memory devices, mobile phones, and high-frequency communications. For instance, in 3D IC packaging, 3D NAND, and high-bandwidth memory (HBM), wafer stacking greatly improves integration and performance, enabling storage devices and processors to offer more functions within the same physical space. Furthermore, as packaging technologies advance, managing power consumption and heat dissipation has become increasingly important. The industry has proposed various solutions to tackle these issues. Therefore, wafer stacking technology not only meets the current demands for miniaturization and high performance but also opens up new possibilities for the future development of semiconductor products.

### SUMMARY OF THE INVENTION

In view of this, the present invention provides a wafer stacking structure and its fabricating process to reduce package size and increase yield.

According to an embodiment of the present invention, a wafer stacking structure includes numerous device wafers. Each of the device wafers is respectively designated as an Nth device wafer, wherein N=1, 2, . . . , M, M≥3, and N is a positive integer that increases sequentially in Arabic numerical order starting from 1 to define a series of Nth device wafers. The Nth device wafers are stacked from bottom to top to form a wafer stacking structure. The Nth device wafer with a larger N is positioned below the Nth device wafer with a smaller N. When N=M, an Mth device wafer is the bottommost wafer in the wafer stacking structure, when N=1, a 1st device wafer is the topmost wafer in the wafer stacking structure. Each of the Nth device wafers includes an Nth front surface and an Nth back surface. An Nth metal interconnection of each of the Nth device wafers is embedded within an Nth dielectric layer, and the Nth metal interconnection and the Nth dielectric layer cover and contact the Nth front surface of each of the Nth device wafers. Edges of all the Nth device wafers are aligned to form a plane when N=1, 2, . . . , M−1, and an edge of an Mth dielectric layer of the Mth device wafer protrudes from the plane.

According to another embodiment of the present invention, a fabricating process of a wafer stacking structure includes providing a silicon carrier wafer including a top surface and a bottom surface. Next, a series of device wafers is provided. Each of the device wafers is respectively designated as an Nth device wafer, wherein N=1, 2, . . . , M, M≥3, and N is a positive integer that increases sequentially in Arabic numerical order starting from 1. The Nth device wafer includes an Nth front surface and an Nth back surface. An Nth metal interconnection of the Nth device wafer is embedded within an Nth dielectric layer, the Nth metal interconnection and the Nth dielectric layer cover and contact the Nth front surface of the Nth device wafer, and the Nth silicon vias are embedded into the Nth device wafer from the Nth front surface of the Nth device wafer. Next, a first silicon oxide layer is formed to cover and contact the top surface of the silicon carrier wafer. Later, a second silicon oxide layer is formed to cover and contact a 1st metal interconnection and a 1st dielectric layer on a 1st device wafer when N=1. After forming the first silicon oxide layer and the second silicon oxide layer, a first bonding process is performed to bond the second silicon oxide layer on the 1st device wafer to the first silicon oxide layer on the silicon carrier wafer when N=1. Subsequently, when N=2, . . . , M, a second bonding process is performed repeatedly until an Mth device wafer is bonded, wherein the second bonding process includes bonding the Nth metal interconnection and the Nth dielectric layer on the Nth device wafer to an (N−1)th device wafer. After the second bonding process, the bottom surface of the silicon carrier wafer is thinned and an edge of the silicon carrier wafer is trimmed. Finally, the silicon carrier wafer which is thinned is immersed in an etching solution to completely remove the silicon carrier wafer.

According to yet another embodiment of the present invention, a fabricating process of a wafer stacking structure includes forming a wafer stacking structure, wherein the wafer stacking structure includes numerous device wafers, each of the device wafers is respectively designated as an Nth device wafer, wherein N=1, 2, . . . , M, M≥3, and N is a positive integer that increases sequentially in Arabic numerical order starting from 1 to form a series of Nth device wafers. The Nth device wafers are stacked from bottom to top to form the wafer stacking structure. The Nth device wafer with a larger N is positioned below the Nth device wafer with a smaller N. When N=M, an Mth device wafer is the bottommost wafer in the wafer stacking structure, and when N=1, a 1st device wafer is the topmost wafer in the wafer stacking structure. Each of the Nth device wafers includes an Nth front surface and an Nth back surface. An Nth metal interconnection of each of Nth device wafers is embedded within an Nth dielectric layer, and the Nth metal interconnection and the Nth dielectric layer cover and contact the Nth front surface of each of the Nth device wafers. Edges of all the Nth device wafers are aligned to form a plane when N=1, 2, . . . , M−1, and an edge of an Mth dielectric layer of the Mth device wafer protrudes from the plane.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 9 depict a fabricating process of a wafer stacking structure according to a first embodiment of the present invention, wherein:

FIG. 1 depicts an Nth device wafer and a silicon carrier wafer;

FIG. 2 depicts a fabricating stage in continuous of FIG. 1;

FIG. 3 depicts a fabricating stage in continuous of FIG. 2;

FIG. 4 depicts a fabricating stage in continuous of FIG. 3;

FIG. 5 depicts a fabricating stage in continuous of FIG. 4;

FIG. 6 depicts a fabricating stage in continuous of FIG. 5;

FIG. 7 depicts a fabricating stage in continuous of FIG. 6;

FIG. 8 depicts a fabricating stage in continuous of FIG. 7; and

FIG. 9 depicts a fabricating stage in continuous of FIG. 8.

FIG. 10 to FIG. 13 depict a fabricating process of a wafer stacking structure according to a second embodiment of the present invention, wherein:

FIG. 10 depicts a first bonding process;

FIG. 11 depicts a fabricating stage in continuous of FIG. 10;

FIG. 12 depicts a fabricating stage in continuous of FIG. 11; and

FIG. 13 depicts a fabricating stage in continuous of FIG. 12.

### DETAILED DESCRIPTION

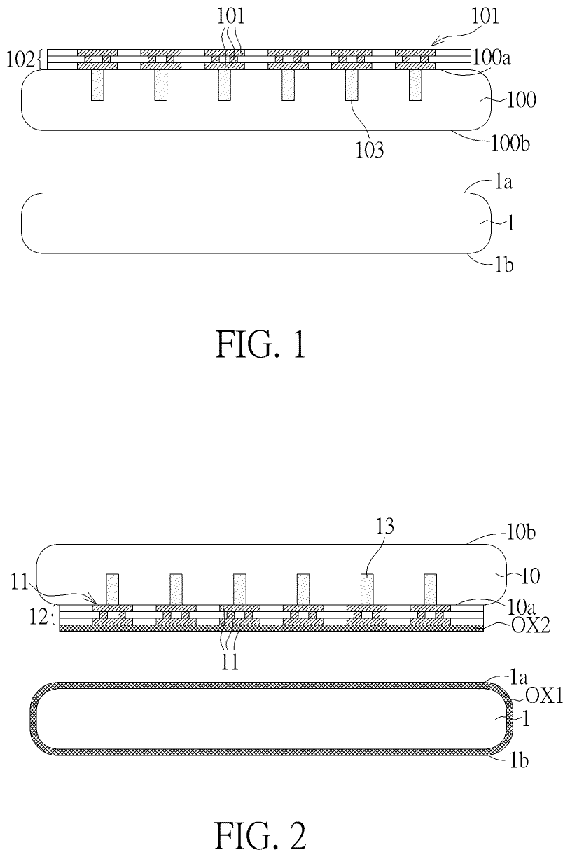

FIG. 1 to FIG. 9 depict a fabricating process of a wafer stacking structure according to a first embodiment of the present invention.

As shown in FIG. 1, a silicon carrier wafer 1 is provided. The silicon carrier wafer 1 includes a top surface 1a and a bottom surface 1b. The top surface 1a is opposite to the bottom surface 1b. The material of the silicon carrier wafer 1 includes monocrystalline silicon, polycrystalline silicon, amorphous silicon, or silicon-on-insulator wafers. The material of the silicon carrier wafer 1 is opaque. Additionally, the Young's modulus of the silicon carrier wafer 1 is greater than that of glass. According to an embodiment of the present invention, the Young's modulus of the silicon carrier wafer 1 is between 130 and 190 GPa, but is not limited to this range.

Moreover, numerous device wafers are provided. Each of the device wafers is designated as an Nth device wafer 100. The materials of the Nth device wafers 100 include semiconductor materials or insulating materials. Semiconductor materials include silicon, germanium, gallium arsenide, silicon germanium, indium phosphide, gallium nitride, or silicon carbide, but are not limited to these materials. Insulating materials include silicon oxide, silicon nitride, silicon oxynitride, or tetraethoxysilane, but are not limited to these materials. Furthermore, N=1, 2, . . . , M, where M≥3.

According to a preferred embodiment of the present invention, M≥6, and N is a positive integer that increases sequentially in Arabic numerical order starting from 1. Each of the Nth device wafers 100 includes a front surface 100a and a back surface 100b. The front surface 100a and the back surface 100b are opposite to each other. An Nth metal interconnection 101 is embedded in an Nth dielectric layer 102, and the Nth metal interconnection 101 and the Nth dielectric layer 102 cover and physically contact the Nth front surface 100a of each of the Nth device wafers 100. Numerous Nth silicon vias 103 are embedded into each of the Nth device wafers 100 from the Nth front surface 100a of each of the Nth device wafers 100. The manufacturing method of the Nth metal interconnection 101 includes etching the Nth dielectric layer 102 to form a recess, followed by filling the recess with metal. The manufacturing method of the Nth silicon vias 103 includes etching the Nth front surface 100a of the Nth device wafer 100 to form a recess, followed by filling the recess with metal. The metal used for the Nth silicon vias 103 and the Nth metal interconnection 101 includes copper, aluminum, or other conductive materials. The material of the Nth dielectric layer 102 includes silicon oxide, silicon nitride, silicon oxynitride, tetraethoxysilane, or low dielectric constant materials. Components such as transistors, capacitors, inductors, or dynamic random-access memory (DRAM) can be disposed on the Nth front surface 100a of the Nth device wafer 100. In one embodiment, the Nth device wafer 100 includes numerous DRAM chips or numerous logic chips.

As shown in FIG. 2, when N=1, the Nth device wafer becomes a 1st device wafer 10. The 1st device wafer 10 includes a 1st front surface 10a and a 1st back surface 10b. The 1st metal interconnection 11 is embedded in the 1st dielectric layer 12, and the 1st metal interconnection 11 and the 1st dielectric layer 12 cover and contact the 1st front surface 10a of the 1st device wafer 10. Numerous 1st silicon vias 13 are embedded from the 1st front surface 10a of the 1st device wafer 10 into the 1st device wafer 10.

Please still refer to FIG. 2. A first silicon oxide layer OX1 is formed to cover and contact the top surface 1a of the silicon carrier wafer 1. The fabricating method of the first silicon oxide layer OX1 includes a thermal oxidation process or a deposition process. If a thermal oxidation process is used, the first silicon oxide layer OX1 will encapsulate the entire silicon carrier wafer 1 completely. Additionally, a second silicon oxide layer OX2 is formed to cover and contact the 1st metal interconnection 11 and the 1st dielectric layer 12 on the 1st device wafer 10. The fabricating method of the second silicon oxide layer OX2 includes a deposition process or a thermal oxidation process. According to one embodiment, a thickness of the first silicon oxide layer OX1 is between 10 to 19,000 angstroms, and a thickness of the second silicon oxide layer OX2 is between 10 to 19,000 angstroms. Both the first silicon oxide layer OX1 and the second silicon oxide layer OX2 include silicon dioxide.

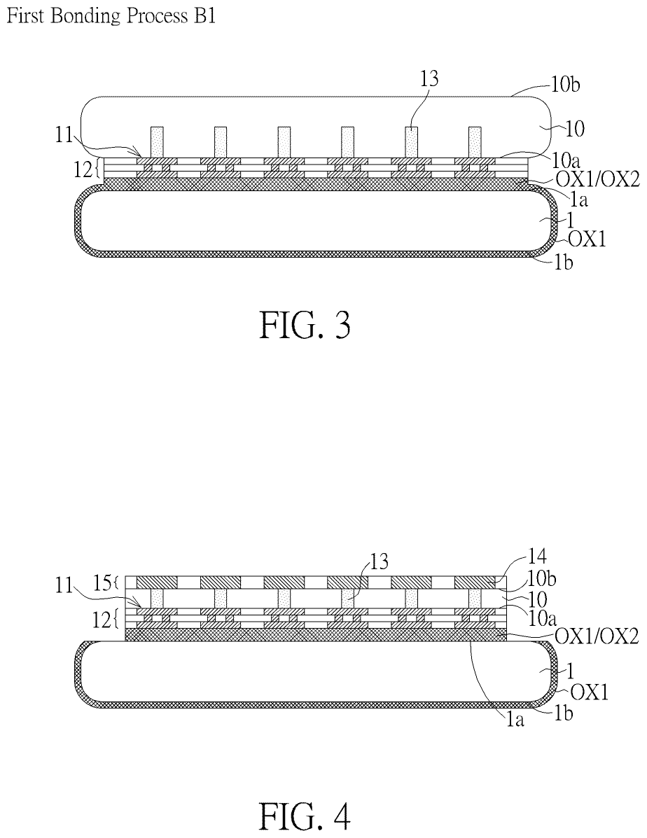

As shown in FIG. 3, a first bonding process B1 is performed to bond the second silicon oxide layer OX2 on the 1st device wafer 10 to the first silicon oxide layer OX1 on the silicon carrier wafer 1. The first bonding process B1 uses silicon dioxide wafer bonding. At this point, the front surface 10a of the 1st device wafer 10 faces the top surface 1a of the silicon carrier wafer 1.

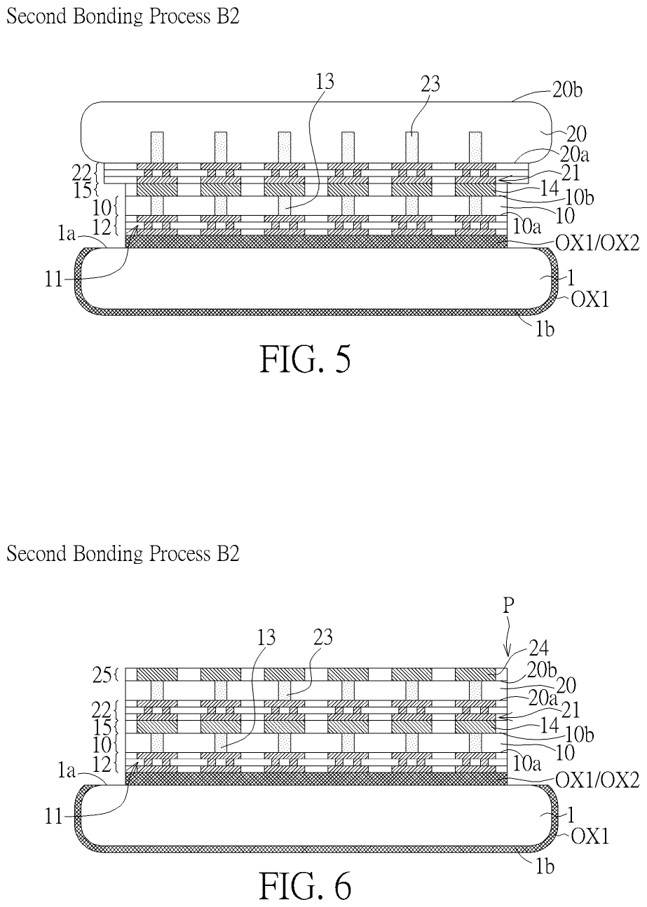

As shown in FIG. 4, an edge of the 1st device wafer 10 is trimmed followed by thinning the 1st back surface 10b of the 1st device wafer 10 to expose the 1st silicon vias 13 on the 1st device wafer 10. After the 1st device wafer 10 is trimmed, the diameter of the 1st device wafer 10 is reduced, and after thinning, the thickness of the 1st device wafer 10 becomes smaller. The thinning process of the 1st device wafer 10 can be performed through chemical mechanical polishing (CMP), and the trimming process of the 1st device wafer 10 can be performed by using an edge grinding process. In subsequent embodiments of the first embodiment, the thinning process can always be performed by using chemical mechanical polishing, and the trimming process can always be performed by using the edge grinding process. Then, numerous 1st conductive lines 14 and a 1st insulating layer 15 are formed to cover the 1st back surface 10b of the 1st device wafer 10. Each of the 1st conductive lines 14 contacts a corresponding one of the 1st silicon vias 13 on the 1st device wafer 10. The 1st conductive lines 14 include copper, aluminum, or other conductive materials. The 1st insulating layer 15 includes silicon oxide, silicon nitride, silicon oxynitride, tetraethoxysilane, or low dielectric constant materials. The 1st conductive lines 14 include a single layer of conductive pads. However, based on different requirements, the 1st conductive lines 14 may also include multiple conductive pads and multiple conductive plugs stacked alternately.

As shown in FIG. 5 to FIG. 7, when N=2, . . . , M, the value of N increases sequentially in Arabic numerals. A second bonding process B2 is repeatedly performed until the Mth device wafer is bonded. For example, if M=4, the 2nd device wafer, the 3rd device wafer, and the 4th device wafer are stacked from bottom to top on the 1st device wafer.

In detail, when N=2, . . . , M−1, the second bonding process B2 includes bonding the Nth metal interconnection and the Nth dielectric layer on the Nth device wafer to the (N−1)th device wafer. The second bonding process B2 uses a hybrid bonding process. However, before bonding the Nth metal interconnection and the Nth dielectric layer on the Nth device wafer to the (N−1)th device wafer, the edge of the (N−1)th device wafer and the edge of the (N−1)th dielectric layer are trimmed. Afterwards, the (N−1)th back surface of the (N−1)th device wafer is thinned to expose each of the (N−1)th silicon vias on the (N−1)th device wafer. Then, numerous (N−1)th conductive lines and an (N−1)th insulating layer are formed to cover the (N−1)th back surface of the (N−1)th device wafer. Each of the (N−1)th conductive lines contacts a corresponding one of the (N−1)th silicon vias on the (N−1)th device wafer. The Nth metal interconnection and the Nth dielectric layer on the Nth device wafer are bonded to the (N−1)th conductive lines and the (N−1)th insulating layer, respectively. In this embodiment, the Nth conductive lines include copper, aluminum, or other conductive materials, and the Nth insulating layer includes silicon oxide, silicon nitride, silicon oxynitride, tetraethoxysilane, or low dielectric constant materials.

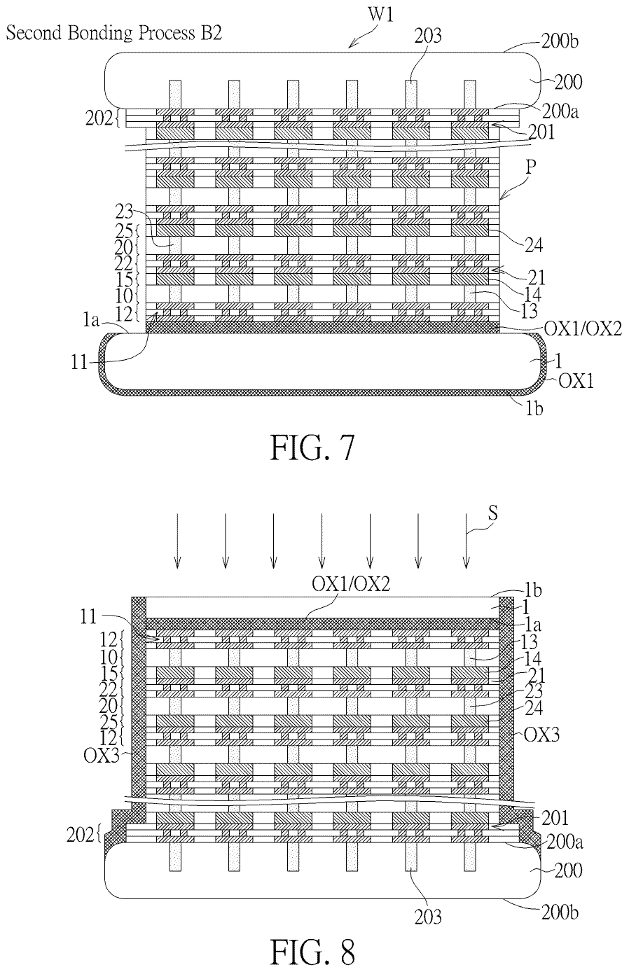

Specifically, as shown in FIG. 5, when N=2, the Nth device wafer becomes the 2nd device wafer 20. The 2nd device wafer 20 includes the 2nd front surface 20a and the 2nd back surface 20b. In the second bonding process B2, the 2nd metal interconnection 21 on the 2nd device wafer 20 is bonded to each of the 1st conductive lines 14 on the 1st device wafer 10. Every pad or plug of the 2nd metal interconnection 21 respectively contacts a corresponding one of 1st conductive lines 14. The 2nd dielectric layer 22 on the 2nd device wafer 20 is bonded to the 1st insulating layer 15 on the 1st device wafer 10. Later, as shown in FIG. 6, after trimming the edge of the 2nd device wafer 20 and the edge of the 2nd dielectric layer 22, the 2nd back surface 20b of the 2nd device wafer 20 is thinned to expose each of the 2nd silicon vias 23 on the 2nd device wafer 20. Then, numerous 2nd conductive lines 24 and a 2nd insulating layer 25 are formed to cover the 2nd back surface 20b of the 2nd device wafer 20. Each of the 2nd conductive lines 24 respectively contacts the 2nd silicon vias 23 on the 2nd device wafer 20. Furthermore, when trimming the edge of the 2nd device wafer 20 and the edge of the 2nd dielectric layer 22, the edge of the 2nd device wafer 20 and the edge of the 2nd dielectric layer 22 are aligned with the trimmed edges of the 1st device wafer 10 and the 1st dielectric layer 12. After the trimming process for the edge of the 2nd device wafer 20 and the edge of the 2nd dielectric layer 22, the trimmed edge of the 2nd device wafer 20, the trimmed edge of the 2nd dielectric layer 22, the trimmed edge of the 1st device wafer 10, and the trimmed edge of the 1st dielectric layer 12 form a plane P. As shown in FIG. 7, the Nth device wafer is stacked in the same way as stacking the 2nd device wafer 20 until N=M−1. At this point, the edge of the 1st device wafer 10 to the edge of (M−1)th device wafer, as well as the edge of the 1st dielectric layer 12 to the edge of the (M−1)th dielectric layer, will all be aligned with the plane P. It is worth noting that after bonding the Mth metal interconnection 201 and the Mth dielectric layer 202 on the Mth device wafer 200 to the (M−1)th device wafer, the edge of the Mth device wafer 200 and the edge of the Mth dielectric layer 202 are not trimmed, and the Mth back surface 200b of the Mth device wafer 200 is not thinned. Therefore, the edge of the Mth dielectric layer 202 and the edge of the Mth device wafer 200 protrude from the plane P, and the Mth silicon vias 203 are not exposed from the back surface 200b of the Mth device wafer 200. At this point, a wafer stacking structure W1 is formed.

As shown in FIG. 8, after flipping the wafer stacking structure W1 upside down, the silicon carrier wafer 1 is the topmost layer, and the Mth device wafer 200 is the bottommost layer. Next, after thinning the bottom surface 1b of the silicon carrier wafer 1 and trimming the edge of the silicon carrier wafer 1, a third silicon oxide layer OX3 is formed to cover the edge of the 1st device wafer 10 to the edge of the (M−1)th device wafer, the edge of the 1st dielectric layer 12 to the edge of the Mth dielectric layer 202, and the edge of the silicon carrier wafer 1. The thinning process of the silicon carrier wafer 1 can be performed using chemical mechanical polishing. If glass is used as the carrier wafer, due to the need for chemical mechanical polishing and the fact that the Young's modulus of glass is lower than that of silicon, glass may fracture during the chemical mechanical polishing process. Therefore, in the first embodiment, glass cannot be used as the carrier wafer. As shown in FIG. 8 to FIG. 9, the thinned silicon carrier wafer 1 is immersed in an etching solution S to completely remove the silicon carrier wafer 1, thereby exposing the first silicon oxide layer OX1. The etching solution S includes an alkaline solution with a pH greater than 13. According to one embodiment, the etching solution S includes tetramethylammonium hydroxide (TMAH). Then, the first silicon oxide layer OX1 and the second silicon oxide layer OX2 are patterned to expose the first metal interconnection 11 on the 1st device wafer 10. At this point, the wafer stacking structure W2 is completed. The wafer stacking structure W2 can then be sent to the subsequent wafer packaging and testing processes. Afterward, the wafer stacking structure W2 can be diced into several chip stacking structures.

Please refer to both FIG. 1 and FIG. 9. A wafer stacking structure W2 includes numerous Nth device wafers 100, wherein N=1, 2, . . . , M, and M≥3. N is a positive integer that starts from 1 and increases sequentially in Arabic numeral order. All the Nth device wafers 100 are stacked from bottom to top to form the wafer stacking structure W2. The Nth device wafer with a larger N is positioned below the Nth device wafer with a smaller N. When N=M, the Mth device wafer 200 is the bottommost wafer of the wafer stacking structure W2. When N=1, the 1st device wafer 10 is the topmost wafer of the wafer stacking structure W2. The Nth device wafer 100 includes an Nth front surface 100a and an Nth back surface 100b. An Nth metal interconnection 101 is embedded in an Nth dielectric layer 102, and the Nth metal interconnection 101 covers and contacts the Nth front surface 100a of the Nth device wafer 100. When N=1, 2, . . . , M−1, the edges of all the Nth device wafers 100 are aligned to form a plane P, while the edge of the Mth dielectric layer 202 of the Mth device wafer 200 protrudes from the plane P.

Moreover, a first silicon oxide layer OX1 and a second silicon oxide layer OX2 cover the first metal interconnection 11 and the first dielectric layer 12 on the first device wafer 10. The first metal interconnection 11 is exposed through the first silicon oxide layer OX1 and the second silicon oxide layer OX2. A single layer of first silicon oxide layer OX1 and a single layer of second silicon oxide layer OX2 are stacked together to form a silicon oxide block. Numerous separate silicon oxide blocks respectively cover and contact the first metal interconnection 11. A third silicon oxide layer OX3 covers and contacts the plane P and the edge of the Mth dielectric layer 202 of the Mth device wafer 200. Additionally, each Nth device wafer 100 may include multiple DRAM chips or multiple logic chips, and the types of chips on each Nth device wafer 100 can vary. For example, the 1st device wafer 10 includes multiple DRAM chips, while the 2nd device wafer 20 includes multiple logic chips.

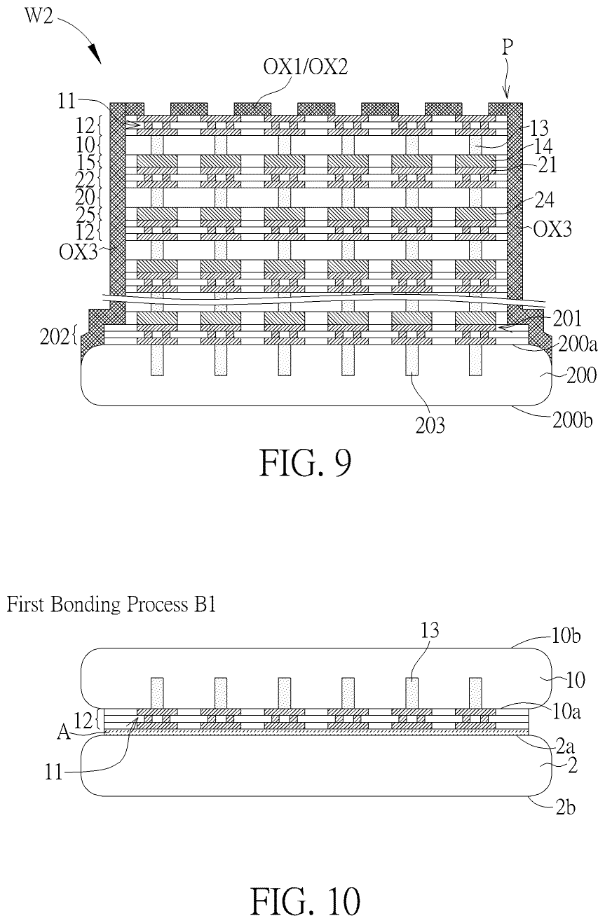

FIG. 10 to FIG. 13 depict a fabricating process of a wafer stacking structure according to a second embodiment of the present invention, wherein elements which are substantially the same as those in the first embodiment are denoted by the same reference numerals; an accompanying explanation is therefore omitted. The difference between the second embodiment and the first embodiment is that the carrier wafer in the second embodiment is not a silicon carrier wafer. In the second embodiment, the carrier wafer is not removed by using an etching solution; instead, the carrier wafer is separated from the 1st device wafer by removing an adhesive. In the second embodiment, the stacking method from the 1st device wafer to the Mth device wafer is the same as that in the first embodiment. For detailed stacking processes of the 1st device wafer to the Mth device wafer, please refer to the first embodiment.

As shown in FIG. 10, a carrier wafer 2 is provided. The carrier wafer includes a top surface 2a and a bottom surface 2b. The top surface 2a and bottom surface 2b is opposite to each other. The carrier wafer 2 includes glass, metal, resin, ceramic or other supporting materials. Next, a 1st device wafer 10 is provided. Then, a first bonding process B1 is performed to bond the 1st device wafer 10 to the carrier wafer 2. Specifically, an adhesive A is provided to cover the top surface 2a of the carrier wafer 2. Later, the first dielectric layer 12 contacts adhesive A. Next, the adhesive A is heated and cured to bond the 1st device wafer 10 to the carrier wafer 2. The adhesive A includes polymer adhesives, such as epoxy resin, polyimide, or acrylic resin, but is not limited to these.

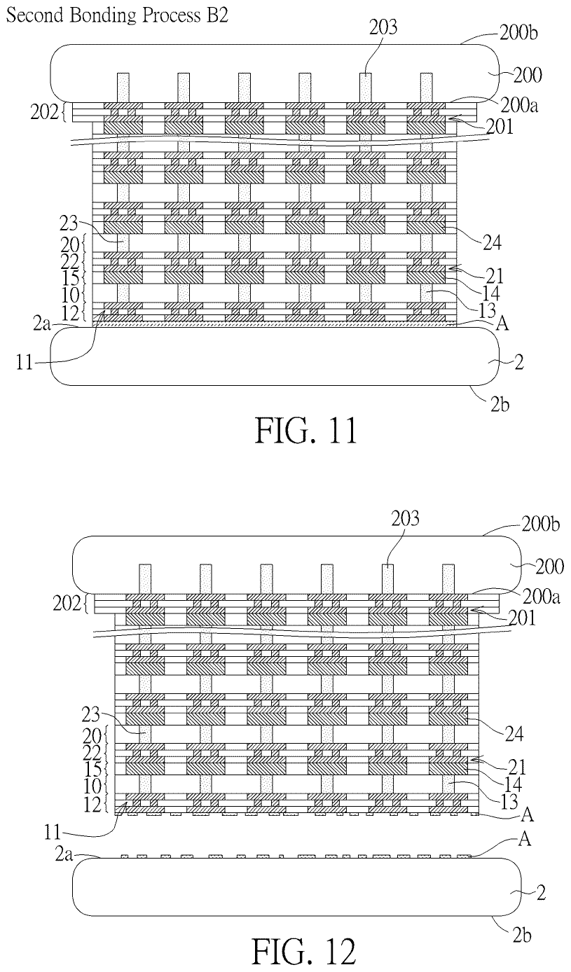

As shown in FIG. 11, a second bonding process B2 is performed. When N=2, . . . , M, N is increased sequentially in Arabic numeral order. The second bonding process B2 is repeated until the Mth device wafer 200 is bonded. The 2nd device wafer 20 to the (M−1)th device wafer undergo the same edge trimming process, the same thinning process, the same formation of the 2nd conductive lines 24 to the (M−1) conductive lines, and the same formation of the 2nd insulating layers 25 to the (M−1) insulating layers as those in the first embodiment. Similarly, the Mth device wafer 200 is not subjected to an edge trimming or a back surface thinning.

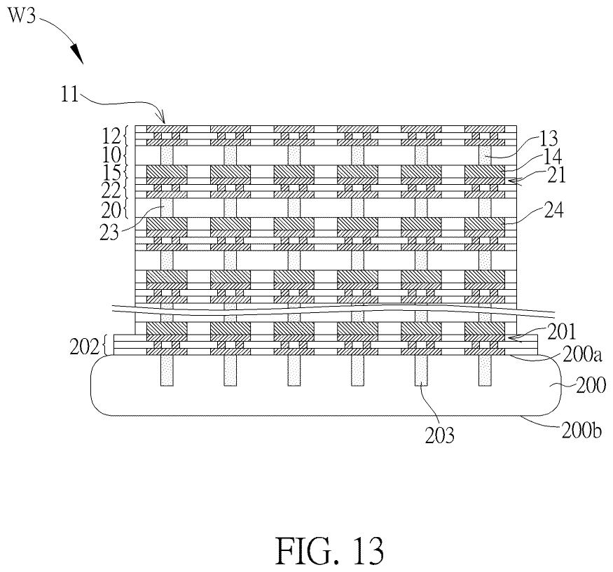

As shown in FIG. 12, the carrier wafer 2 is debonded. The debonding methods include a chemical debonding process, a thermal release debonding process, a laser debonding process, or a mechanical debonding process, but are not limited to these processes. The main goal of the debonding process is to remove adhesive A or to remove the adhesiveness of adhesive A to separate the carrier wafer 2 and the 1st device wafer 10, while the body of the carrier wafer 2 is not decomposed. However, the silicon carrier wafer 1 in the first embodiment is decomposed by the etching solution S. As shown in FIG. 13, the 1st dielectric layer 12 is planarized to expose the 1st metal interconnection 11, and to remove any of the adhesive A which remains on the 1st dielectric layer 12. At this point, the wafer stacking structure W3 is completed.

The multiple device wafers in the present invention are bonded by using hybrid bonding. The metal interconnections and silicon vias directly contact each other to electrically connect the upper and lower device wafers. Compared to the bonding method that utilizing a wire bonding to electrical connect the upper and lower device wafers, the method of the present invention allows the wafer stacking structure to achieve a smaller size. Additionally, when the silicon carrier wafer is removed by using an etching solution described in the first embodiment, damage to the chips on the device wafer during the debonding process of the carrier wafer can be avoided, and the step of removing residual adhesive can also be omitted.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A wafer stacking structure, comprising:
a plurality of device wafers, each of the plurality of device wafers being respectively designated as an Nth device wafer, wherein N=1, 2, . . . , M, M≥3, and N is a positive integer which increases sequentially in Arabic numerical order starting from 1 to define a plurality of Nth device wafers, the plurality of Nth device wafers are stacked from bottom to top to form a wafer stacking structure, the Nth device wafer with a larger N is positioned below the Nth device wafer with a smaller N, when N=M, an Mth device wafer is the bottommost wafer in the wafer stacking structure, when N=1, a 1st device wafer is the topmost wafer in the wafer stacking structure, each of the plurality of Nth device wafers comprises an Nth front surface and an Nth back surface, an Nth metal interconnection of each of the plurality of Nth device wafers is embedded within an Nth dielectric layer, and the Nth metal interconnection and the Nth dielectric layer cover and contact the Nth front surface of each of the plurality of Nth device wafers; wherein edges of all the Nth device wafers are aligned to form a plane when N=1, 2, . . . , M−1, and an edge of an Mth dielectric layer of the Mth device wafer protrudes from the plane.

2. The wafer stacking structure of claim 1, further comprising a first silicon oxide layer and a second silicon oxide layer covering a 1st metal interconnection and a 1st dielectric layer on the 1st device wafer, wherein the 1st metal interconnection is exposed through the first silicon oxide layer and the second silicon oxide layer.

3. The wafer stacking structure of claim 2, further comprising a third silicon oxide layer covering and physically contacting the plane and the edge of the Mth dielectric layer of the Mth device wafer.

4. The wafer stacking structure of claim 1, wherein each of the plurality of Nth device wafers comprises a plurality of DRAM chips or a plurality of logic chips.

5. A fabricating process of a wafer stacking structure, comprising:
providing a silicon carrier wafer comprising a top surface and a bottom surface;
providing a plurality of device wafers, each of the plurality of device wafers being respectively designated as an Nth device wafer, wherein N=1, 2, . . . , M, M≥3, and N is a positive integer that increases sequentially in Arabic numerical order starting from 1, and wherein the Nth device wafer comprises an Nth front surface and an Nth back surface, an Nth metal interconnection of the Nth device wafer is embedded within an Nth dielectric layer, the Nth metal interconnection and the Nth dielectric layer cover and contact the Nth front surface of the Nth device wafer, and a plurality of Nth silicon vias are embedded into the Nth device wafer from the Nth front surface of the Nth device wafer;
forming a first silicon oxide layer covering and contacting the top surface of the silicon carrier wafer;
forming a second silicon oxide layer to cover and contact a 1st metal interconnection and a 1st dielectric layer on a 1st device wafer when N=1;
after forming the first silicon oxide layer and the second silicon oxide layer, performing a first bonding process to bond the second silicon oxide layer on the 1st device wafer to the first silicon oxide layer on the silicon carrier wafer when N=1;
when N=2, . . . , M, performing a second bonding process repeatedly until an Mth device wafer being bonded, wherein the second bonding process comprises:
bonding the Nth metal interconnection and the Nth dielectric layer on the Nth device wafer to an (N−1)th device wafer;
after the second bonding process, thinning the bottom surface of the silicon carrier wafer and trimming an edge of the silicon carrier wafer; and
immersing the silicon carrier wafer which is thinned in an etching solution to completely remove the silicon carrier wafer.

6. The fabricating process of a wafer stacking structure of claim 5, further comprising:
after removing the silicon carrier wafer, patterning the first silicon oxide layer and the second silicon oxide layer to expose the 1st metal interconnection on the 1st device wafer.

7. The fabricating process of a wafer stacking structure of claim 5, further comprising:
after the first bonding process, trimming an edge of the 1st device wafer and then thinning a 1st back surface of the 1st device wafer to expose a plurality of 1st silicon vias on the 1st device wafer; and
forming a plurality of 1st conductive lines and a 1st insulation layer to cover the 1st back surface of the 1st device wafer, wherein each of the plurality of 1st conductive lines respectively contacts one of the plurality of 1st silicon vias on the 1st device wafer.

8. The fabricating process of a wafer stacking structure of claim 7, wherein the second bonding process further comprising:
bonding a 2nd metal interconnection on a 2nd device wafer to the plurality of 1st conductive lines on the 1st device wafer; and
after trimming an edge of the 2nd device wafer, thinning a 2nd back surface of the 2nd device wafer to expose a plurality of 2nd silicon vias on the 2nd device wafer.

9. The fabricating process of a wafer stacking structure of claim 7, wherein when N=2, . . . , M−1, the second bonding process further comprising:
before bonding the Nth metal interconnection and the Nth dielectric layer on the Nth device wafer to the (N−1)th device wafer, trimming an edge of the (N−1)th device wafer following thinning an (N−1)th back surface of the (N−1)th device wafer to expose a plurality of (N−1)th silicon vias on the (N−1)th device wafer;
forming a plurality of (N−1)th conductive lines and an (N−1)th insulation layer which covers an (N−1)th back surface of the (N−1)th device wafer, wherein each of the plurality of (N−1)th conductive lines contacts a corresponding one of the plurality of (N−1)th silicon vias on the (N−1)th device wafer; wherein the Nth metal interconnection and the Nth dielectric layer on the Nth device wafer bond to the plurality of (N−1)th conductive lines and the (N−1)th insulation layer.

10. The fabricating process of a wafer stacking structure of claim 7, wherein when N=M, after bonding an Mth metal interconnection and an Mth dielectric layer on the Mth device wafer to an (M−1)th device wafer, an edge of the Mth device wafer are not trimmed, and the Mth back surface of the Mth device wafer is not thinned.

11. The fabricating process of a wafer stacking structure of claim 5, wherein the etching solution comprises a solution with a pH greater than 13.

12. The fabricating process of a wafer stacking structure of claim 5, wherein the Nth device wafer comprises a plurality of DRAM chips or a plurality of logic chips.

13. The fabricating process of a wafer stacking structure of claim 5, wherein the silicon carrier wafer is opaque.

14. The fabricating process of a wafer stacking structure of claim 5, further comprising when N=1, 2, . . . , M, before immersing the silicon carrier wafer which is thinned in the etching solution, forming a third silicon oxide layer that covers an edge of the Nth device wafer and an edge of the Nth dielectric layer.

15. A fabricating process of a wafer stacking structure, comprising:
forming a wafer stacking structure, wherein the wafer stacking structure comprises:
a plurality of device wafers, each of the plurality of device wafers being respectively designated as an Nth device wafer, wherein N=1, 2, . . . , M, M≥3, and N is a positive integer that increases sequentially in Arabic numerical order starting from 1 to form a plurality of Nth device wafers, the plurality of Nth device wafers are stacked from bottom to top to form the wafer stacking structure, the Nth device wafer with a larger N is positioned below the Nth device wafer with a smaller N, when N=M, an Mth device wafer is the bottommost wafer in the wafer stacking structure, when N=1, a 1st device wafer is the topmost wafer in the wafer stacking structure, each of the plurality of Nth device wafers comprises an Nth front surface and an Nth back surface, an Nth metal interconnection of each of the plurality of Nth device wafers is embedded within an Nth dielectric layer, and the Nth metal interconnection and the Nth dielectric layer cover and contact the Nth front surface of each of the plurality of Nth device wafers; wherein edges of all the Nth device wafers are aligned to form a plane when N=1, 2, . . . , M−1, and an edge of an Mth dielectric layer of the Mth device wafer protrudes from the plane.

16. The fabricating process of a wafer stacking structure of claim 15, further comprising: forming a first silicon oxide layer covering a 1st metal interconnection and a 1st dielectric layer on the 1st device wafer, wherein the 1st metal interconnection is exposed through the first silicon oxide layer.

17. The fabricating process of a wafer stacking structure of claim 15, further comprising forming a third silicon oxide layer covering and physically contacting the plane and the edge of the Mth dielectric layer of the Mth device wafer.

18. The fabricating process of a wafer stacking structure of claim 15, wherein each of the plurality of Nth device wafers comprises a plurality of DRAM chips or a plurality of logic chips.
